(19) United States
(12) Patent Application Publication
(10) Pub. No.: US 2005/0112903 A1
(43) Pub. Date: May 26, 2005

(54) Process for removing tungsten particles after tungsten etch-back

(75) Inventors: Chih-Chun Yang, Taipei City (TW); Tung-Chin Yeh, Hsin chu (TW)

Correspondence Address: TUNG & ASSOCIATES;Suite 120, 838 W. Long Lake Road, Bloomfield Hills, MI, 48302, US

(73) Assignee: Taiwan Semiconductor Manufacturing Co., Ltd.

(21) Appl. No.: 10/719,550

(22) Filed: Nov. 21, 2003

(51) Int. Cl. H01L 21/302; H01L 21/461

(52) U.S. Cl. 438/745

(57) ABSTRACT

A new and improved process which is effective in removing tungsten residues from a tungsten plug structure after a tungsten etchback process is carried out on the structure. The tungsten plug structure is fabricated by providing a bottom dielectric layer on a substrate, providing a bottom metal layer on the bottom dielectric layer, providing a top dielectric layer on the bottom metal layer, providing a via opening in the top dielectric layer, filling the via opening with tungsten, and removing the excess tungsten layer by tungsten etchback. The process of the invention includes removal of tungsten residues from the tungsten plug structure by application of an oxidant solution to the structure after the excess tungsten layer is etched from the structure and prior to deposit of a top metal layer on the tungsten plugs.

### FIELD OF THE INVENTION

The present invention relates to tungsten etch-back processes used in the formation of tungsten plugs between conductive metal layers on a semiconductor wafer substrate. More particularly, the present invention relates to a process for removing tungsten residues from a substrate after a tungsten etch-back process is carried out on the substrate.

### BACKGROUND OF THE INVENTION

The fabrication of various solid state devices requires the use of planar substrates, or semiconductor wafers, on which integrated circuits are fabricated. The final number, or yield, of functional integrated circuits on a wafer at the end of the IC fabrication process is of utmost importance to semiconductor manufacturers, and increasing the yield of circuits on the wafer is the main goal of semiconductor fabrication. After packaging, the circuits on the wafers are tested, wherein non-functional dies are marked using an inking process and the functional dies on the wafer are separated and sold. IC fabricators increase the yield of dies on a wafer by exploiting economies of scale. Over 1000 dies may be formed on a single wafer which measures from six to twelve inches in diameter.

Various processing steps are used to fabricate integrated circuits on a semiconductor wafer. These steps include deposition of a conducting layer on the silicon wafer substrate; formation of a photoresist or other mask such as titanium oxide or silicon oxide, in the form of the desired metal interconnection pattern, using standard lithographic or photolithographic techniques; subjecting the wafer substrate to a dry etching process to remove the conducting layer from the areas not covered by the mask, thereby etching the conducting layer in the form of the masked pattern on the substrate; removing or stripping the mask layer from the substrate typically using reactive plasma and chlorine gas, thereby exposing the top surface of the conductive interconnect layer; and cooling and drying the wafer substrate by applying water and nitrogen gas to the wafer substrate.

The numerous processing steps outlined above are used to cumulatively apply multiple electrically conductive and insulative layers on the wafer and pattern the layers to form the circuits. The final yield of functional circuits on the wafer depends on proper application of each layer during the process steps. Proper application of those layers depends, in turn, on coating the material in a uniform spread over the surface of the wafer in an economical and efficient manner. The various layers define circuit components or devices such as transistors.

After the individual devices have been fabricated on the substrate, they must be connected together to perform the desired circuit functions. This interconnection process is generally known as “metallization” and is performed using a number of different photolithographic, deposition, and removal techniques. In a common interconnection process, two interconnect channels of conductor materials are separated by interlayer dielectric layers in vertically separated planes perpendicular to each other and interconnected by a vertical connection, or “via”, at their closest point.

Tungsten metal is commonly used to fill via openings between vertically-spaced metal conductive layers in a device. A technique commonly used in the formation of tungsten plugs is known as tungsten etchback, shown in FIGS. 1A-1D. The tungsten etchback technique is carried out on a via structure 8 in which a bottom dielectric layer 12 is deposited on a substrate 10, a bottom metal layer 14 is deposited on the bottom dielectric layer 12, a top dielectric layer 16 is deposited on the bottom metal layer 14, and a barrier layer 17 which is typically TiN is deposited on the top dielectric layer 16. As shown in FIG. 1A, multiple via openings 18 are etched through the top dielectric layer 16. Next, as shown in FIG. 13, tungsten plugs 22 are formed in a tungsten plug structure 9 typically by chemical vapor deposition (CVD) of tungsten in the via openings 18. A tungsten layer 20 is simultaneously formed on the barrier layer 17 as the via openings 18 are filled with the tungsten plugs 22.

A dry plasma etchback step is used to remove the tungsten layer 20 from the barrier layer 17 and leave the tungsten plugs 22 intact, as shown in FIG. 1C. Tungsten etch can be carried out using a fluorine-based or chlorine-based etchant. Use of the fluorine-based etchants frequently causes the formation of residual tungsten residues 24, having the formula TiFₓ(SOₙ)_{y}(H₂O)_{z}, on the tungsten plugs 22 and barrier layer 17. The tungsten residues 24 must be removed from the structure 9 prior to subsequent processing. Finally, as shown in FIG. 1D, a top metal layer 26 is deposited on the barrier layer 17, in electrical contact with the tungsten plugs 22, to complete fabrication of the tungsten plug structure 9.

In the semiconductor fabrication industry, minimization of particle contamination on device structures increases in importance as the integrated circuit devices on the wafers decrease in size. With the reduced size of the devices, a contaminant having a particular size occupies a relatively larger percentage of the available space for circuit elements on the wafer as compared to wafers containing the larger devices of the past. Moreover, the presence of particles in the integrated circuits compromises the functional integrity of the devices in the finished electronic product. Currently, mini-environment based IC manufacturing facilities are equipped to control airborne particles much smaller than 1.0 m, as surface contamination continues to be of high priority to semiconductor manufacturers. To achieve an ultraclean wafer surface, particles must be removed from the wafer, and particle-removing methods are therefore of utmost importance in the fabrication of semiconductors.

The most common method for removing the tungsten residues 24 from the tungsten plug structure 9 is the wet scrubbing method, in which a jet of high-pressure deionized water sprayed against the structure 9. In addition, a scrubber brush may be simultaneously applied against the structure 9. The water jet is normally sprayed at a pressure of about 2,000-3,000 psi. It has been found, however, that the wet scrubber method is ineffective in completely removing the tungsten residues from the tungsten plug structure prior to deposit of the top metal layer on the top dielectric layer and tungsten plugs. While an in-situ post-etch bake process may be used immediately after the tungsten etchback process to prevent formation of the residues, this post-etch bake fails to remove the residues after they have formed. Accordingly, a new and improved process for the removal of tungsten residues from a tungsten plug or other structure is needed.

An object of the present invention is to provide a new and improved method which is suitable for removing tungsten residues from a substrate during fabrication of semiconductor integrated circuits on a wafer substrate.

Another object of the present invention is to provide a new and improved method which is effective in the removal of tungsten residues from a tungsten plug structure during a tungsten etchback process.

Still another object of the present invention is to provide a new and improved method which includes the use of a strong oxidant solution to remove tungsten residues from a wafer substrate.

Yet another object of the present invention is to provide a method which is suitable for removing tungsten residues formed as a result of a tungsten etchback process from tungsten plugs prior to deposition of a metal layer on the tungsten plugs.

A still further object of the present invention is to provide a method which is effective for removing tungsten residues from a tungsten plug structure using an oxidant solution which includes hydroxylamine.

Yet another object of the present invention is to provide a new and improved method which may be used for removing tungsten residues from surfaces in a variety of applications.

### SUMMARY OF THE INVENTION

In accordance with these and other objects and advantages, the present invention generally relates to a new and improved process which is effective in removing tungsten residues from a tungsten plug structure after a tungsten etchback process is carried out on the structure. The tungsten plug structure is fabricated by providing a bottom dielectric layer on a substrate, providing a bottom metal layer on the bottom dielectric layer, providing a top dielectric layer on the bottom metal layer, providing a via opening in the top dielectric layer, filling the via opening with tungsten, and removing the excess tungsten layer by tungsten etchback. The process of the invention includes removal of tungsten residues from the tungsten plug structure by application of an oxidant solution to the structure after the excess tungsten layer is etched from the structure and prior to deposit of a top metal layer on the tungsten plugs.

In a preferred embodiment, the process of the present invention is carried out using an oxidant solution including hydroxylamine. Preferably, the hydroxylamine is present in the oxidant solution in concentrations of from about 11% to about 13% by weight. In a most preferred embodiment, the hydroxylamine is present in the oxidant solution in concentrations of about 12%. The oxidant solution may further include catechol (4˜8 wt. %), diglycolamine (5˜8 wt. %), gallic acid (1˜3 wt. %), monoethanolamine (22˜28 wt. %), and monoisopropanolamine (19˜23 wt. %). The oxidant solution is applied to the tungsten plug structure at an operating temperature of typically from about 60 degrees C. to about 80 degrees C.

### BRIEF DESCRIPTION OF THE DRAWINGS

The invention will now be described, by way of example, with reference to the accompanying drawings, in which:

FIG. 1A is a cross-sectional view of a via structure with multiple via openings as a precursor to the fabrication of a tungsten plug structure according to a conventional process;

FIG. 1B is a cross-sectional view of a tungsten plug structure fabricated by filling via openings with tungsten, according to a conventional process;

FIG. 1C is a cross-sectional view of a tungsten plug structure after tungsten etchback removal of an excess tungsten layer from the structure of FIG. 1B, according to a conventional process, more particularly illustrating tungsten residues formed on the structure;

FIG. 1D is a cross-sectional view of a tungsten plug structure completed according to a conventional process;

FIG. 2A is a cross-sectional view of a via structure with multiple via openings as a precursor to a tungsten plug structure prior to implementation of the process of the present invention;

FIG. 2B is a cross-sectional view of a tungsten plug structure fabricated by filling via openings with tungsten prior to implementation of the process of the present invention;

FIG. 2C is a cross-sectional view of a tungsten plug structure after tungsten etchback removal of an excess tungsten layer from the structure of FIG. 1B, prior to implementation of the process of the present invention, more particularly illustrating tungsten residues formed on the structure;

FIG. 2D is a cross-sectional view of a tungsten plug structure illustrating application of a solvent solution to the structure to remove tungsten residues therefrom in accordance with the present invention;

FIG. 2E is a cross-sectional view of the tungsten plug structure with the tungsten residues removed therefrom as a result of the step of FIG. 2D; and

FIG. 2F is a cross-sectional view of the tungsten plug structure following deposition of a metal layer on the tungsten plugs to complete the structure.

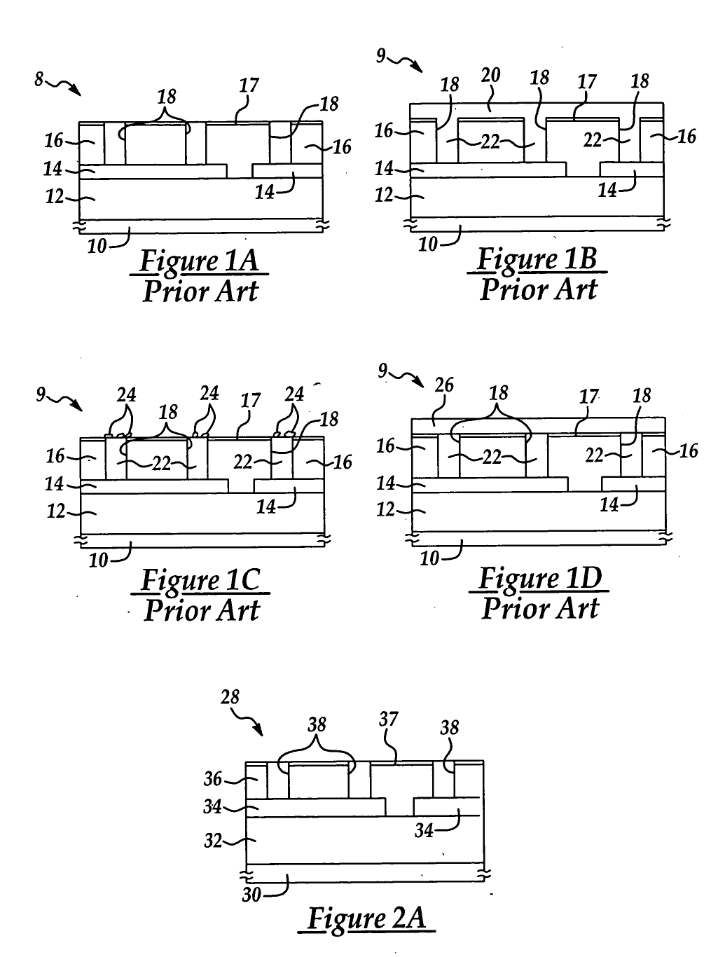

### DESCRIPTION OF THE PREFERRED EMBODIMENTS

The present invention has particularly beneficial utility in the removal of tungsten residues from a tungsten plug structure during a tungsten etchback process for the fabrication of tungsten plugs in a semiconductor fabrication process. However, the process of the invention is not so limited in application and may be more generally applicable to removal of tungsten residues from substrates in a variety of industrial and mechanical applications.

The present invention is generally directed to a novel process for the removal of tungsten residues from a work-in-progress tungsten plug structure during a tungsten etchback process. In such a process, a bottom dielectric layer, a bottom metal layer, and a top dielectric layer are sequentially deposited on a substrate. Via openings are etched through the top dielectric layer and then filled with tungsten to form tungsten plugs therein. An excess tungsten layer above the tungsten plugs is removed by tungsten etchback, typically in conventional fashion. According to the process of the present invention, tungsten residues resulting from the tungsten etchback process are removed from the tungsten plug structure by the application of an oxidant solution to the structure. The oxidant solution oxidizes and dissolves the tungsten residues, preparatory to deposition of a top metal layer on the top dielectric layer. The top metal layer is disposed in electrical contact with the bottom metal layer through the tungsten plugs.

In a preferred embodiment, the process of the present invention is carried out using an oxidant solution including hydroxylamine. Preferably, the hydroxylamine is present in the oxidant solution in concentrations of from about 11% to about 13% by weight, and most preferably, about 12% by weight. The oxidant solution may further include catechol (about 4˜8 wt. %), diglycolamine (about 5˜8 wt. %), gallic acid (about 1˜3 wt. %), monoethanolamine (about 22˜28 wt. %), and monoisopropanolamine (about 19˜23 wt. %). The oxidant solution is applied to the tungsten plug structure at an operating temperature of typically from about 60 degrees C. to about 80 degrees C.

The invention may be carried out using the oxidant solution EKC270, available from EKC Technology, Inc., of Hayward, Calif. Such oxidant solution includes about 4.56˜8.05, and preferably, about 7.17 wt. % catechol; about 5.13˜8.21, and preferably, about 6.93 wt. % diglycolamine; about 1.63˜2.58, and preferably, about 2.21 wt. % gallic acid; about 11.70˜13.44, and preferably, about 12.06 wt. % hydroxylamine; about 24.76˜27.50, and preferably, about 26.03 wt. % moisture; about 22.46˜27.94, and preferably, about 25.36 wt. % monoethanolamine; and about 18.98˜23.02, and preferably, about 21.12 wt. % monoisopropanolamine.

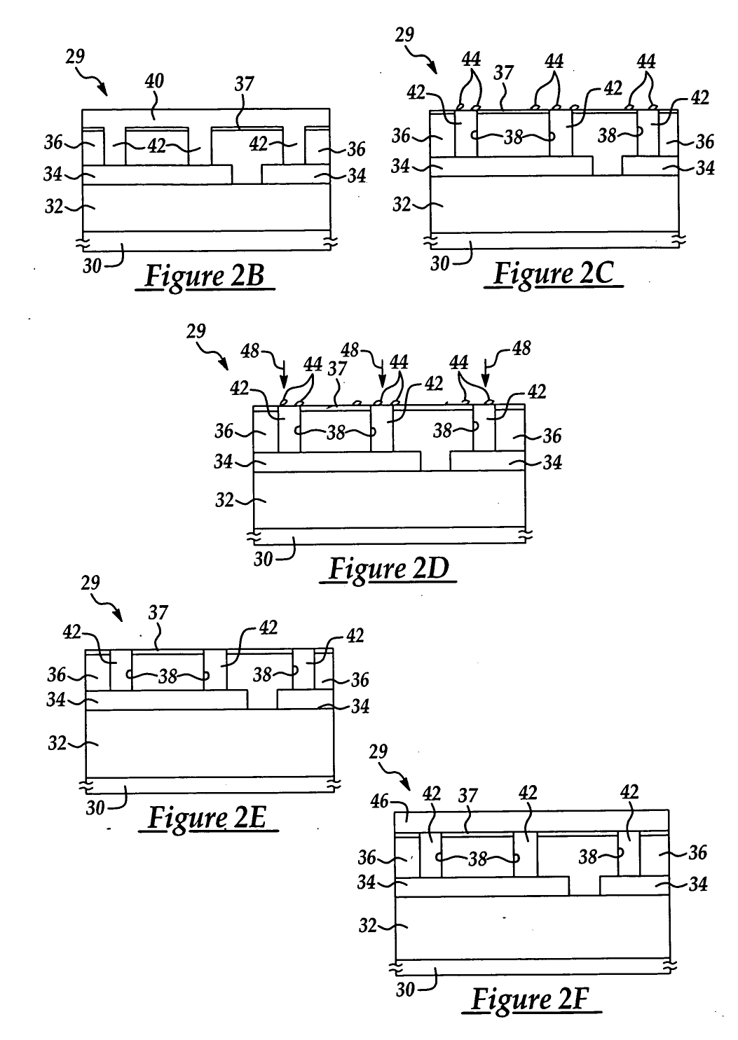

Referring to FIGS. 2A-2F, the present invention is particularly applicable to a tungsten etchback for the formation of a tungsten plug structure 29 on a substrate 30. The tungsten etchback process begins with fabrication of a via structure 28 on the substrate 30, as shown in FIG. 2A. Accordingly, a bottom dielectric layer 32 is typically initially deposited on the substrate 30, followed by deposition of a bottom metal layer 34 on the bottom dielectric layer 32, a top dielectric layer 36 on the bottom metal layer 34, and a typically TiN barrier layer 37 on the top dielectric layer 36. The bottom dielectric layer 32, the metal layer 34, the top dielectric layer 36 and the barrier layer 37 may be formed using conventional physical vapor deposition techniques, according to the knowledge of those skilled in the art. Via openings 38 are then patterned and etched through the barrier layer 37 and underlying top dielectric layer 36. The bottom of the via openings 38 expose the upper surface of the bottom metal layer 34.

After the via openings 38 are etched through the top dielectric layer 36, the via openings 38 are blanket-deposited with liquid tungsten metal, typically using a conventional chemical vapor deposition (CVD) process, to define tungsten plugs 42 in the respective via openings 38, as shown in FIG. 2B. During tungsten-filling of the via openings 38, a tungsten layer 40 is simultaneously formed on the upper surface of the barrier layer 37. Accordingly, the tungsten layer 40 must be removed from the barrier layer 37 using a tungsten etchback process prior to resuming fabrication of the tungsten plug structure 29.

The tungsten etchback process typically includes two steps. In the first step, 90% of the tungsten layer 40 is etched at a high rate with excellent uniformity. In the second step, the etch rate is reduced and a gas chemistry is reduced with a high selectivity to the barrier layer 37. The etch reduction serves to decrease gas pressure and wafer temperature to reduce loading effects that may cause recesses in the tungsten plugs 42.

After the tungsten etchback process, tungsten residues 44 typically remain on the upper surfaces of the tungsten plugs 42 and barrier layer 37, as shown in FIG. 2C. According to the process of the present invention, the substrate 30 with the tungsten plug structure 29 is next typically placed in a wet etch tool (not shown) to facilitate dissolving and removal of the tungsten residues 44 from the tungsten plugs 38 and barrier layer 37. As shown in FIG. 2D, an oxidant solution 48, which may be the oxidant solution EKC270 available from EKC technology, Inc. of Hayward, Calif., for example, is heated typically to a temperature of from about 60 degrees C. to about 80 degrees C., and then sprayed against the upper surfaces of the barrier layer 37 and the tungsten plugs 42. Alternatively, the tungsten plug structure 29 may be immersed in the oxidant solution 48 for a period of typically about 3 min. to about 30 min. Accordingly, as shown in FIG. 2E, the oxidant solution 48 thoroughly dissolves and removes the tungsten residues 44 from the structure 29.

As shown in FIG. 2F, after dissolving and removal of the tungsten residues 44 from the structure 29, in the manner heretofore described, a top metal layer 46 is deposited on the barrier layer 37 typically using a conventional CVD process. The top metal layer 46 is disposed in electrical contact with the bottom metal layer 34 through the tungsten plugs 42. It will be appreciated by those skilled in the art that the process of the present invention removes residues which could otherwise potentially provide a large resistance that would adversely affect operation of the device including the tungsten plug structure 29.

While the preferred embodiments of the invention have been described above, it will be recognized and understood that various modifications can be made in the invention and the appended claims are intended to cover all such modifications which may fall within the spirit and scope of the invention.

1. A process for removing residues from a structure, comprising the steps of:
providing an oxidant solution;
heating said oxidant solution to a temperature of at least about 60 degrees C.; and
applying said oxidant solution to the structure.

2. The process of claim 1 wherein said oxidant solution comprises hydroxylamine.

3. The process of claim 1 wherein said applying said oxidant solution to the structure comprises spraying said oxidant solution onto the structure.

4. The process of claim 3 wherein said oxidant solution comprises hydroxylamine.

5. The process of claim 1 wherein said heating said oxidant solution to a temperature of at least about 60 degrees C. comprises heating said oxidant solution to a temperature of from about 60 degrees C. to about 80 degrees C.

6. The process of claim 5 wherein said oxidant solution comprises hydroxylamine.

7. The process of claim 5 wherein said applying said oxidant solution to the structure comprises spraying said oxidant solution onto the structure.

8. The process of claim 7 wherein said oxidant solution comprises hydroxylamine.

9. A process for removing residues from a tungsten plug structure, comprising the steps of:
providing an oxidant solution; and
applying said oxidant solution to the tungsten plug structure.

10. The process of claim 9 wherein said oxidant solution comprises hydroxylamine.

11. The process of claim 9 wherein said applying said oxidant solution to the structure comprises spraying said oxidant solution onto the structure.

12. The process of claim 9 further comprising the step of heating said oxidant solution to a temperature of at least about 60 degrees C. prior to said applying said oxidant solution to the tungsten plug structure.

13. A process for removing residues from a tungsten plug structure having at least one tungsten plug and a tungsten layer, comprising the steps of:
etching said tungsten layer from said tungsten plug structure;
providing an oxidant solution; and
removing the residues from the tungsten plug structure by applying said oxidant solution to the tungsten plug structure.

14. The process of claim 13 wherein said oxidant solution comprises hydroxylamine.

15. The process of claim 13 wherein said applying said oxidant solution to the tungsten plug structure comprises spraying said oxidant solution onto the tungsten plug structure.

16. The process of claim 15 wherein said oxidant solution comprises hydroxylamine.

17. The process of claim 13 further comprising the step of heating said oxidant solution to a temperature of at least about 60 degrees C. prior to said applying said oxidant solution to the tungsten plug structure.

18. The process of claim 17 wherein said oxidant solution comprises hydroxylamine.

19. The process of claim 17 wherein said applying said oxidant solution to the tungsten plug structure comprises spraying said oxidant solution onto the tungsten plug structure.

20. The process of claim 19 wherein said oxidant solution comprises hydroxylamine.
